(19) United States
(12) Patent Application Publication
(10) Pub. No.: US 2011/0199113 A1
(43) Pub. Date: Aug. 18, 2011

(54) INSERT CONTAINING APPARATUS FOR SEMICONDUCTOR PACKAGE

(76) Inventor: Young-chul Lee, Asan-si (KR)

(21) Appl. No.: 13/014,774

(22) Filed: Jan. 27, 2011

(30) Foreign Application Priority Data
Feb. 12, 2010 (KR) 10-2010-0013511

(51) Int. Cl. G01R 31/20; H01L 21/677; H01L 21/68; B23Q 3/00

(52) U.S. Cl. 324/757.04; 414/589; 414/222.01; 269/289 R

(57) ABSTRACT

An insert containing apparatus for a semiconductor package. The insert containing apparatus for a semiconductor package includes: a tray; an insert that is disposed in the tray, wherein at least one semiconductor package is seated on the insert and a through hole is formed around the semiconductor package; and an adapter including at least one finger of which an end portion passes through the through hole of the insert and guides the semiconductor package to a predetermined position so as to arrange the semiconductor package seated on the insert. The insert containing apparatus for a semiconductor package can be applied to semiconductor packages having any of various sizes by using a size-free insert. Thus, an investment cost of an instrument infrastructure can be greatly reduced, and an exchanging time of an insert can be reduced, and thus human power and time can be reduced.

### CROSS-REFERENCE TO RELATED APPLICATIONS

This application claims the benefit of Korean Patent Application No. 10-2010-0013511, filed on Feb. 12, 2010, in the Korean Intellectual Property Office, the disclosure of which is incorporated by reference herein in its entirety.

### BACKGROUND

The inventive concept relates to an insert containing apparatus for a semiconductor package, and more particularly, to an insert containing apparatus for a semiconductor package that can contain a plurality of semiconductor packages having various sizes in a tray by using a bottom-up type adapter that is moved up from below the tray and coupled to the tray.

After a wafer forming process is finished, a semiconductor chip separated from the wafer can be manufactured as a semiconductor package through a predetermined assembling process. Semiconductor packages manufactured through the predetermined processes undergo various tests to ensure reliability of a product.

In general, the test includes an electrical property test, a burn-in test, and etc. The electrical property test is performed to check electrical properties of a semiconductor chip and to determine whether defects are present. The burn-in test is performed to check lifespan of a semiconductor chip under severe conditions, for example, at a temperature and a pressure that are higher than those of a normal operating condition, and is another test to check whether defects are present. The electrical property test checks a normal operation and disconnection state of a semiconductor chip by placing an input/output terminal of the semiconductor chip on a test circuit substrate on which a test signal generating circuit is formed. A handler may often be used in the electrical property test of a semiconductor package.

A test tray for containing the plurality of semiconductor packages is used while performing the electrical property tests to rapidly perform electrical property tests a plurality of times on the semiconductor packages. An insert containing apparatus for a semiconductor package for containing the semiconductor packages in the test tray by using an insert and an adapter is used to arrange the semiconductor packages at a predetermined position of the test tray.

In such a conventional insert containing apparatus for a semiconductor package, the adapter, which is disposed on the test tray, moves down toward the test tray to be coupled with the insert, and then a picker arranges semiconductor packages at a predetermined position on the insert while guided by the insert.

However, if such a conventional top-down type adapter is used, a plurality of adapters different in size and a plurality of inserts different in size and corresponding to the adapters are required to contain a plurality of semiconductor packages different in size, thereby significantly increasing the number of adapters and inserts corresponding to the adapters.

### SUMMARY

The inventive concept provides an insert containing apparatus for a semiconductor package that allows a single general-purpose insert to be applied to a plurality of semiconductor packages having various sizes by using a bottom-up type adapter that is moved up from below a tray and coupled to the tray.

According to an embodiment of the inventive concept, there is provided an insert containing apparatus for a semiconductor package including a tray, an insert that is disposed in the tray, wherein at least one semiconductor package is seated on the insert and a through hole is formed around the semiconductor package, and an adapter including at least one finger of which an end portion passes through the through hole of the insert and guides the semiconductor package to a predetermined position so as to arrange the semiconductor package seated on the insert.

The insert may include an insert body that is attachable to and detachable from the tray and includes an opening through which the semiconductor package passes, and a frame that is attachable to and detachable from the opening of the insert body and includes the through hole having a size sufficient for the finger having any of various sizes to pass through, wherein the semiconductor package is seated on the frame.

The insert may further include a latch that is disposed in the insert body and maintains the position of the semiconductor packages seated on the frame.

The latch may include a latch bar of which a part is rotatably hinge-coupled to the insert body and of which an end portion presses against the semiconductor package when seated on the frame and a pusher for lifting up the latch bar when the adapter rises.

The adapter may include an adapter body, and a plurality of the fingers formed in the adapter body and of which each end portion includes a guide inclined surface for guiding one of back, front, right, and left sides of the semiconductor package.

The insert containing apparatus may further include a picker that is disposed on the tray and is adhered to the semiconductor package with a vacuum force, and a picker transfer robot for transferring and lowering the picker toward the insert.

The insert containing apparatus may further include an adapter transfer robot that is disposed under the tray and for transferring and lifting up the adapter toward the insert.

The insert containing apparatus may further include a tray transfer device that transfers the insert containing the semiconductor package together with the tray to a subsequent process.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional side view illustrating a standby state of an insert containing apparatus for a semiconductor package according to an embodiment of the inventive concept;

FIG. 2 is a cross-sectional side view illustrating a moving-up state of an adapter of the insert containing apparatus of FIG. 1;

FIG. 3 is a cross-sectional side view illustrating a moving-down state of a semiconductor package and a moving-down state of a picker of the insert containing apparatus of FIG. 2;

FIG. 4 is a cross-sectional side view illustrating a moving-up state of the picker of the insert containing apparatus of FIG. 3;

FIG. 5 is a cross-sectional side view illustrating a moving-down state of the adapter of the insert containing apparatus of FIG. 4;

FIG. 6 is a perspective view illustrating the insert containing apparatus for a semiconductor package of FIG. 1 according to an embodiment of the inventive concept;

FIG. 7 is a perspective view illustrating bottom surfaces of a tray and an insert of FIG. 6;

FIG. 8 is a perspective view illustrating the adapter, an adapter holder, and an adapter lifting base included in the insert containing apparatus of FIG. 6;

FIG. 9 is a cross-sectional side view illustrating the insert containing apparatus of FIG. 8, according to an embodiment of the inventive concept; and

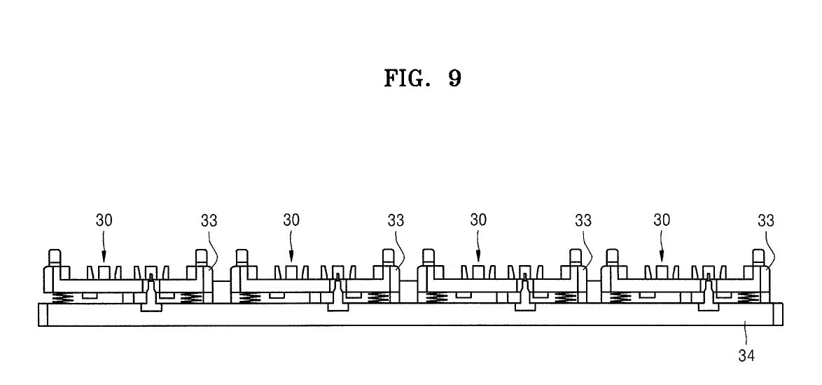

FIG. 10 is a partially enlarged cross-sectional view illustrating an open state of a latch during moving up of the adapter of FIG. 6.

### DETAILED DESCRIPTION OF THE EMBODIMENTS

Now, an insert containing apparatus for a semiconductor package according to exemplary embodiments of the inventive concept will be described in detail with reference to the accompanying drawings.

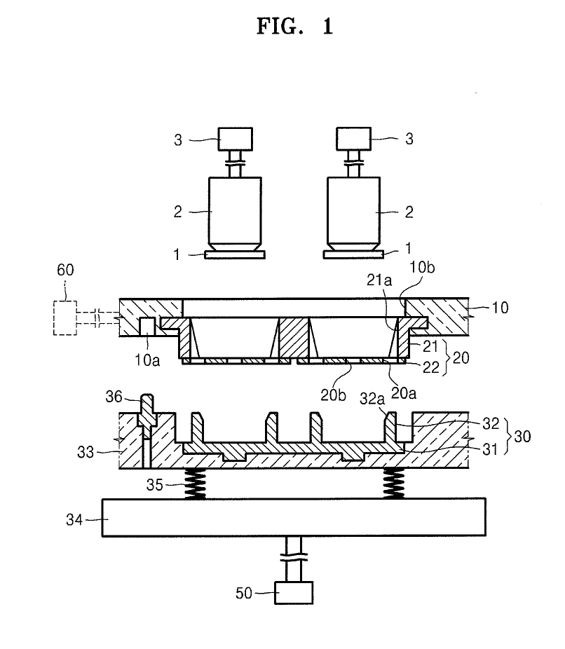

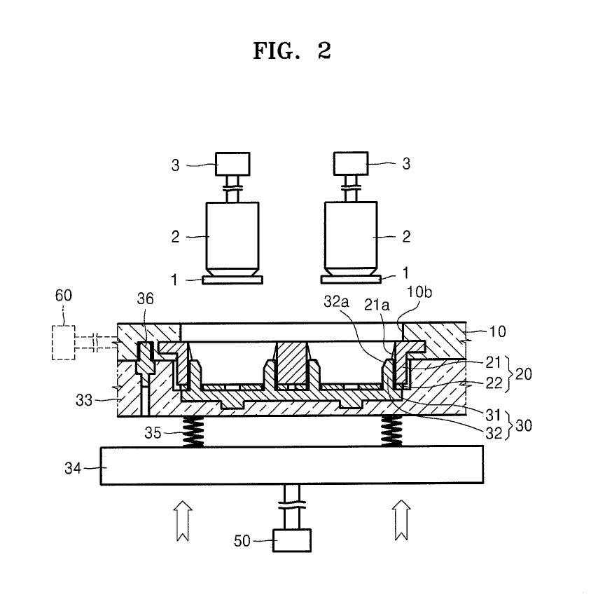

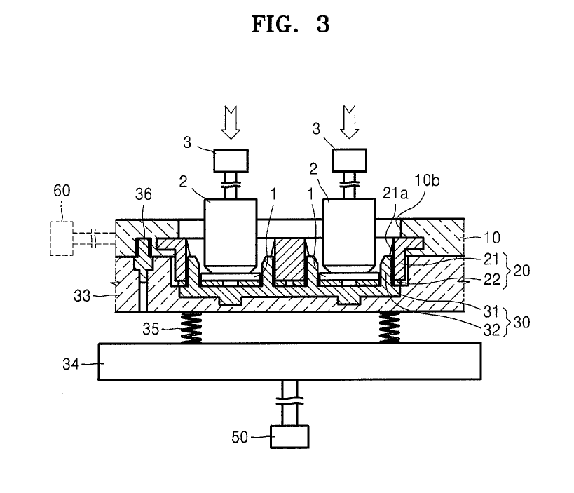

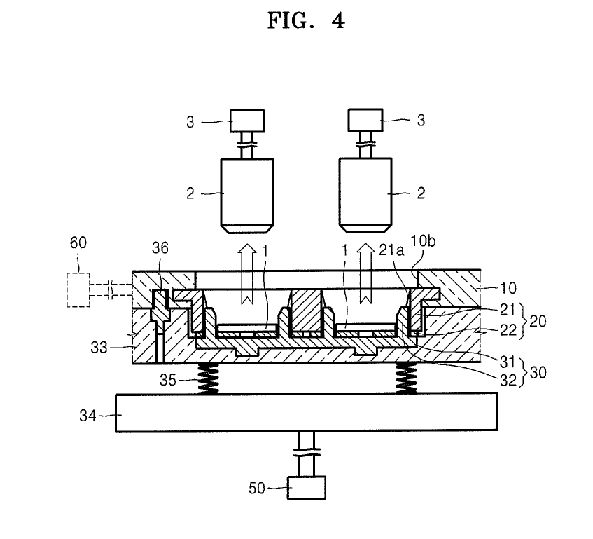

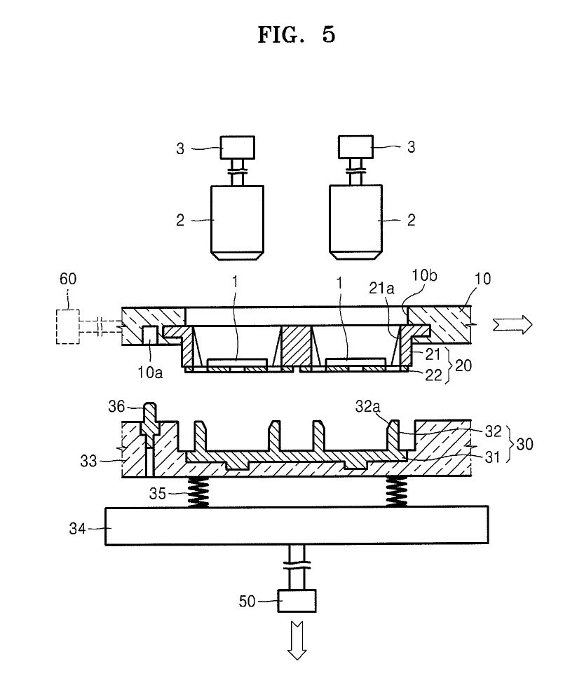

FIGS. 1 through 5 illustrate sequential operations of the insert containing apparatus for a semiconductor package according to an embodiment of the inventive concept. FIG. 1 is a cross-sectional side view illustrating a standby state of the insert containing apparatus for a semiconductor package according to an embodiment of the inventive concept. FIG. 2 is a cross-sectional side view illustrating a moving-up state of an adapter 30 of the insert containing apparatus of FIG. 1. FIG. 3 is a cross-sectional side view illustrating a semiconductor package 1 and a moving-down state of a picker 2 of the insert containing apparatus of FIG. 2. FIG. 4 is a cross-sectional side view illustrating a moving-up state of the picker 2 of the insert containing apparatus of FIG. 3. FIG. 5 is a cross-sectional side view illustrating a moving-down state of the adapter 30 of the insert containing apparatus of FIG. 4.

Referring to FIGS. 1 through 5, the insert containing apparatus for a semiconductor package includes the picker 2 for transferring a semiconductor package 1, a tray 10, an insert 20, and the adapter 30.

As illustrated in FIG. 1, the picker 2 is disposed above the insert 20, and the adapter 30 is disposed under the insert 20. The adapter 30 is a bottom-up type that moves up from below the insert 20 and is coupled with the insert 20.

Also, as illustrated in FIG. 1, the semiconductor package 1 is attached to the picker 2, which is disposed above the tray 10, with a vacuum force, and then the picker 2 moves down toward the insert 20 to be placed on the insert 20. The picker 2 may be connected to a picker transfer robot 3 for transferring and lowering the picker 2 toward the insert 20. The picker transfer robot 3 may include any type of transfer device that may transfer the picker 2.

As illustrated in FIG. 1, the tray 10 may be a test tray for transferring the semiconductor package 1 to a testing process, and may include an insert hole 10b corresponding to the insert 20. Accordingly, the insert 20 is inserted into the insert hole 10b and may be assembled to the insert hole 10b by means of a fastener such as a screw or a bolt. The tray 10 and the insert 20, which contains the semiconductor package 1, together may be transferred to a subsequent process by a tray transfer device 60. The tray transfer device 60 may include various types of conveyor systems or robots.

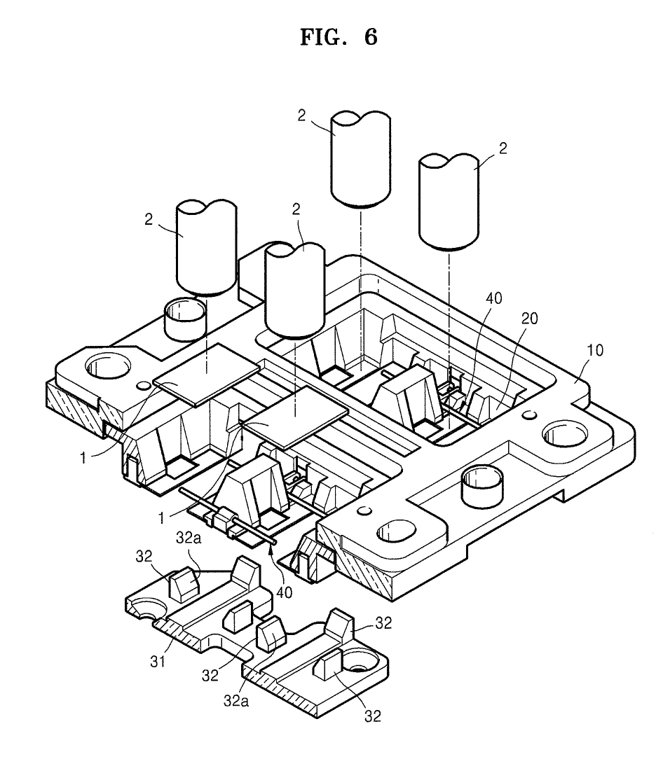

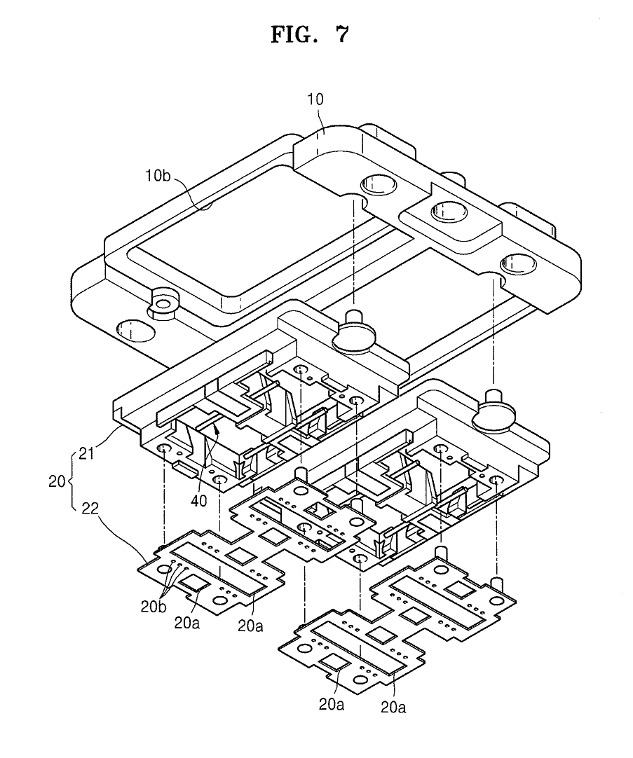

FIG. 6 is a perspective view illustrating the insert containing apparatus for a semiconductor package of FIG. 1. FIG. 7 is a perspective view illustrating bottom surfaces of the tray 10 and the insert 20 of FIG. 6.

As illustrated in FIGS. 1, 6, and 7, the insert 20 is disposed in the tray 10. The semiconductor package 1 is seated in the insert 20, and a through hole 20a is formed around the semiconductor package 1.

The insert 20 may include an insert body 21 and a frame 22, as illustrated in FIGS. 1 and 7. The insert body 21 may be attachable to and detachable from the tray 10, and includes an opening 21a through which the semiconductor package 1 passes.

As illustrated in FIG. 7, the frame 22 may be attachable to and detachable from the opening 21a of the insert body 21, and may include the through hole 20a having a size sufficient for fingers 32 of the adapter 30 having various sizes to pass through. The frame 22 may also include a seating surface on which the semiconductor package 1 is seated. Also, as illustrated in FIG. 7, the frame 22 may include a plurality of terminal openings 20b for a test around the through hole 20a to allow an electrical test to be performed on the arranged semiconductor packages 1.

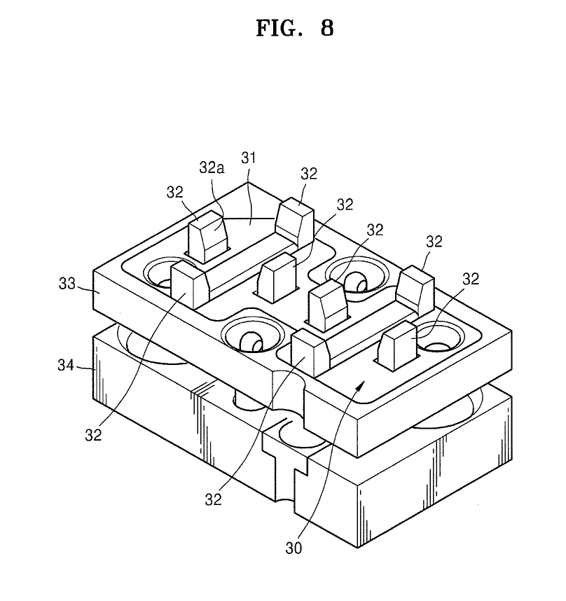

FIG. 8 is a perspective view illustrating the adapter 30, an adapter holder 33, and an adapter lifting base 34 included in the insert containing apparatus of FIG. 6.

As illustrated in FIGS. 1 and 8, the adapter 30 includes at least one finger 32 of which an end portion passes through the through hole 20a of the insert 20 and guides the semiconductor package 1 to a predetermined position to arrange the semiconductor packages 1 on the insert 20. The bottom-up type adapter 30 may include an adapter body 31 disposed under the insert 20, and a plurality of the fingers 32 that are formed in the adapter body 31 and that include guide inclined surfaces 32a for guiding each of back, front, right, and left sides of the semiconductor package 1 on ends of the fingers 32.

The adapter body 31 may be attachable to and detachable from the adapter holder 33 so as to arrange the semiconductor package 1 which may have any of various sizes. The adapter holder 33 may be elastically disposed on the adapter lifting base 34 via a spring 35 so as to reduce an impact generated when the adapter 30 is coupled to the insert 20.

As illustrated in FIG. 1, a guide hole 10a may be formed in the tray 10, and a guide bar 36 engaging with the guide hole 10a may be formed in the adapter holder 33, so that the adapter 30 and the insert 20 are arranged and coupled to each other when the adapter 30 moves up toward the insert 20. Thus, when the adapter 30, the insert 20, and the tray 10 are coupled to one another, positions thereof may be precisely arranged by the guide bar 36 and the guide hole 10a.

As illustrated in FIG. 1, an adapter transfer robot 50 connected to the adapter 30 may be disposed below the tray 10 to drive the bottom-up type adapter 30 and to transfer and lift up the adapter 30 toward the insert 20. The adapter transfer robot 50 may include any type of lifting-up and lowering device that may lift up and lower the adapter 30.

FIG. 1 illustrates the standby state of the insert containing apparatus. As illustrated in FIG. 1, when the tray 10 and the insert 20 are coupled to each other, the semiconductor package 1 is in a standby state over the insert 20, and the adapter 30 is in a standby state under the insert 20. FIG. 2 illustrates the lift-up state of the adapter 30 of FIG. 1. As illustrated in FIG. 2, the adapter 30 is lifted up by the adapter transfer robot 50, and accordingly, the guide bar 36 is inserted into the guide hole 10a, and thus the insert 20 and the adapter 30 are arranged at a predetermined position to be coupled to each other. The finger 32 of the adapter 30 passes through the through hole 20a, which is sufficiently wide for the fingers 32 and is formed in the frame 22, to be positioned at back, front, right, and left sides of a seating surface on which the semiconductor package 1 is to be seated.

FIG. 3 is a cross-sectional side view illustrating the moving-down state of the semiconductor package 1 and the picker 2 of the insert containing apparatus of FIG. 2. As illustrated in FIG. 3, the picker 2 adsorbing the semiconductor package 1 with a vacuum force may allow the semiconductor package 1 to be seated on a seating surface of the frame 22 of the insert 20 by the picker transfer robot 3. The semiconductor package 1 may be guided along the guide inclined surface 32a of the finger 32 having passed through the through hole 20a formed at the back, front, right, and left sides of the seating surface of the semiconductor package Ito be arranged at a predetermined position on the frame 22. The through hole 20a of the frame 22 may have a size sufficient for the fingers 32 having various sizes for the semiconductor package 1 having any of various sizes. Thus, since the insert 20 may be used for a general-purpose, the cost of installing components of the device may be greatly reduced.

FIG. 4 illustrates the moving-up state of the picker 2 of FIG. 3. As illustrated in FIG. 4, the picker 2 may place the semiconductor package 1 on the frame 22, and then move up in an empty state to transfer the next semiconductor package.

FIG. 5 illustrates the moving-down state of the adapter 30 of FIG. 4. As illustrated in FIG. 5, the adapter 30 may be moved down by the adapter transfer robot 50 and return to the standby state at the same time. The tray 10 may be transferred for a subsequent process by the tray transfer device 60.

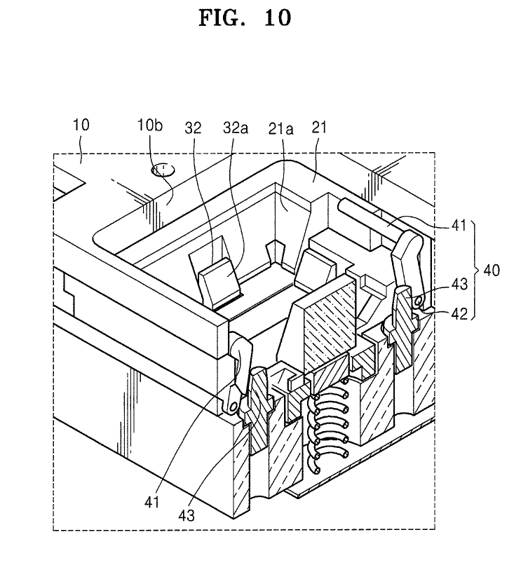

As illustrated in FIGS. 6 and 10, the insert 20 may further include a latch 40 that is disposed in the insert body 21 and maintains the position of the semiconductor package 1 on the frame 22. As illustrated in FIG. 10, the latch 40 includes a latch bar 41 and a pusher 43. A part of the latch bar 41 may be rotatably coupled to the insert body 21 through a hinge shaft 42, and thus, an end of the latch bar 41 may press against the semiconductor package 1. The latch bar 41 may press against the semiconductor package 1 by its own weight or by a restorative force of an additional elastic spring.

When the adapter 30 moves up, the pusher 43, which is disposed in the adapter 30, lifts up the latch bar 41 at the same time.

Accordingly, as illustrated in FIG. 2, when the adapter 30 moves up, the pusher 43 disposed in the adapter 30 lifts up the latch bar 41 to enable the semiconductor package 1 to be loaded. Then, as illustrated in FIG. 4, after the semiconductor package 1 is seated on the insert 20, when the adapter 30 moves down, the pusher 43 disposed in the adapter 30 releases the latch bar 41, and thus the latch bar 41 presses against the semiconductor package 1 by gravity or a restoring force of the elastic spring. Thus, even though the finger 32 is escaped from the frame 22, the position of the arranged semiconductor package 1 may be maintained.

According to the inventive concept, an insert containing apparatus for a semiconductor package can be applied to a semiconductor package having any of various sizes by using a size-free insert. Thus, an investment cost of an instrument infrastructure can be greatly reduced, and an exchanging time of an insert can be reduced, and thus human power and time can be reduced.

While the inventive concept has been particularly shown and described with reference to exemplary embodiments thereof, it will be understood that various changes in form and details may be made therein without departing from the spirit and scope of the following claims.

What is claimed is:

1. An insert containing apparatus for a semiconductor package comprising:
a tray;
an insert that is disposed in the tray, wherein at least one semiconductor package is seated on the insert and a through hole is formed around the semiconductor package; and
an adapter comprising at least one finger of which an end portion passes through the through hole of the insert and guides the semiconductor package to a predetermined position to arrange the semiconductor package seated on the insert.

2. The insert containing apparatus of claim 1, wherein the insert comprises:
an insert body that is attachable to and detachable from the tray and comprises an opening through which the semiconductor package passes; and
a frame that is attachable to and detachable from the opening of the insert body and comprises the through hole having a size sufficient for the finger having any one of various sizes to pass through, wherein the semiconductor package is seated on the frame.

3. The insert containing apparatus of claim 2, wherein the insert further comprises a latch that is disposed in the insert body and maintains the position of the semiconductor package seated on the frame.

4. The insert containing apparatus of claim 3, wherein the latch comprises:
a latch bar of which a part is rotatably hinged to the insert body and of which an end portion presses against the semiconductor package when seated on the frame; and
a pusher lifting up the latch bar when the adapter rises.

5. The insert containing apparatus of claim 1, wherein the adapter comprises:
an adapter body; and
a plurality of the fingers formed in the adapter body and of which each end portion comprises a guide inclined surface guiding one of back, front, right, and left sides of the semiconductor package.

6. The insert containing apparatus of claim 5, wherein the adapter body is attachable to and detachable from an adapter holder to arrange the semiconductor package having any one of various sizes.

7. The insert containing apparatus of claim 6, wherein the adapter holder is elastically disposed in an adapter lifting base via a spring.

8. The insert containing apparatus of claim 1, wherein a guide hole is formed in the tray or the insert, and a guide bar engaged with the guide hole is disposed in the adapter so that when the adapter moves up toward the insert, the adapter and the insert are arranged to be coupled to each other.

9. The insert containing apparatus of claim 1, further comprising:
a picker that is disposed on the tray and adsorbs the semiconductor package with a vacuum force; and
a picker transfer robot transferring and lowering the picker toward the insert.

10. The insert containing apparatus of claim 1, further comprising an adapter transfer robot that is disposed under the tray and for transferring and lifting up the adapter toward the insert.

11. The insert containing apparatus of claim 1, further comprising:
a tray transfer device that transfers the insert containing the semiconductor package together with the tray to a subsequent process.

12. The insert containing apparatus of claim 1, wherein the tray is a test tray transferring the semiconductor package to a testing process.

13. The insert containing apparatus of claim 1, wherein the tray comprises an insert hole corresponding to the insert.

14. The insert containing apparatus of claim 1, wherein the adapter comprises a plurality of terminal openings for a test around the through hole to allow an electrical test to be performed on the arranged semiconductor package.
